(19) United States
(12) Patent Application Publication
(10) Pub. No.: US 2009/0142705 A1
(43) Pub. Date: Jun. 4, 2009

(54) METHOD FOR FORMING MASK PATTERN

(76) Inventor: Sing-Kyung Jung, Bupyeong-gu (KR)

Correspondence Address: SHERR & VAUGHN, PLLC, 620 HERNDON PARKWAY, SUITE 200, HERNDON, VA, 20170, US

(21) Appl. No.: 12/325,161

(22) Filed: Nov. 29, 2008

(30) Foreign Application Priority Data
Nov. 29, 2007 (KR) 10-2007-0122590

(51) Int. Cl. H01L 21/027; G03F 7/20

(52) U.S. Cl. 430/312; 430/325; 430/323

(57) ABSTRACT

A method for forming a mask pattern for forming a semiconductor device may include coating a photoresist, performing a primary bake process on the photoresist, exposing and developing the photoresist, and then performing a secondary bake process on the photoresist under a nitrogen and/or hydrogen gas atmosphere.

The present application claims priority under 35 U.S.C. §119 to Korean Patent Application No. 10-2007-0122590 (filed on Nov. 29, 2007) which is hereby incorporated by reference in its entirety.

### BACKGROUND

A mask pattern is used in various processes for forming a semiconductor device. For example, a mask pattern is used in an etching process, an ion-implantation process, and the like. After a mask pattern such as a HVGX is formed, a deglazing process of removing a portion of a bottom film is performed. However, during the deglazing process, a moat phenomenon is generated in which a certain portion is pitted. After the deglazing, pits caused by the moat phenomenon may be found in a defect inspection.

In a dual gate device, in order to form gate dielectric films, for example, gate oxide films, on and/or over a high-voltage device region Hv and a low-voltage device region Lv, respectively, a thinner gate oxide film is formed on and/or over the high-voltage device region Hv and then a thicker gate oxide film is formed on and/or over the high-voltage device region Hv. In order to sequentially form the gate oxide films having different thickness as described above, a mask pattern is formed on and/or over the low-voltage device region Lv so that only the high-voltage device region Hv is exposed, and then a mask pattern is formed on and/or over the high-voltage device region Hv so that only the low-voltage device region Lv is exposed. Through such a process, the gate oxide films are formed, the gate oxide films each having a thickness finally requested in the high-voltage device region Hv and low-voltage device region Lv.

However, during such a process for forming the mask pattern, exposure and development processes are performed after a photoresist material is coated, and a DI water rinse process for cleaning is performed after a portion exposed to light at the time of exposure is removed. The DI water rinse process is a process which spreads DI water on the substrate, performing a high rotation. During the DI water rinse process, a charging is caused to react chemical substances used in performing a deglazing on the low-voltage device region with a charged region, thereby forming pits resulting from the moat phenomenon. A defect is also generated after the deglazing process. Therefore, in order to reduce generation of charging during the DI water rinse process, there have been attempts to control the overall number of rotations or to reduce the rinse process. However, since the deviation of rotation number and time occurs in every process, such attempts are not complete. In particular, there has been a risk of residue remaining after the process for forming the mask pattern.

### SUMMARY

Embodiments relate to a method for forming a mask pattern that can solve charging caused during a DI water rinse process.

Embodiments relate to a method for forming a mask pattern that does not control the overall number of rotations or rinse process time during a DI water rinse process.

Embodiments relate to a method for forming a mask pattern which improves reliability of the mask pattern by solving charging during a hard bake process for curing photoresist.

Embodiments relate to a method for forming a mask pattern that may include at least one of the following: coating photoresist on and/or over an object; and then performing a primary bake process on and/or over the photoresist; and then exposing and developing the photoresist; and then performing a secondary bake process on the photoresist; and then forming a mask pattern on the object.

Embodiments relate to a method for forming a mask pattern that may include at least one of the following: forming a dielectric film on and/or over a semiconductor substrate having a low-voltage device region and a high-voltage device region; and then coating photoresist on and/or over the dielectric film; and then performing a primary bake process for curing the photoresist; and then exposing and developing the primarily cured photoresist to remove a portion of the primarily cured photoresist exposed to light at the time of exposure; and then performing a secondary bake process for curing the photoresist remaining after the removal.

Embodiments relate to a method for forming a mask pattern that may include at least one of the following: forming a deglazing object on and/or over a semiconductor substrate; and then coating photoresist on and/or over the object; and then performing a soft-bake process for curing the photoresist; and then exposing and developing the photoresist primarily cured by the soft-bake process to remove a portion of the primarily cured photoresist exposed to light at the time of exposure; and then performing a hard-bake process for curing the photoresist remaining after the removal to complete a mask pattern for performing a deglazing on the object.

Embodiments relate to a method that may include at least one of the following: forming a photoresist over an object; and then performing a primary bake process on the photoresist; and then exposing and developing the photoresist; and then performing a secondary bake process on the photoresist; and then forming a mask pattern over the object.

Embodiments relate to a method that may include at least one of the following: forming a dielectric film over a semiconductor substrate having a low-voltage device region and a high-voltage device region; and then coating a photoresist over the dielectric film; and then curing the photoresist by performing a primary bake process; and then exposing and developing the cured photoresist to remove a portion of the cured photoresist; and then recurring the photoresist by performing a secondary bake process after exposing and developing the cured photoresist.

Embodiments relate to a method that may include at least one of the following: forming a deglazing material over a semiconductor substrate; and then coating photoresist over the deglazing material; and then performing a soft-bake process on the photoresist; and then exposing and developing the photoresist after performing the soft-bake process to remove a portion of the photoresist exposed to light at the time of exposure; and then performing a hard-bake process on the photoresist exposing and developing the photoresist.

In accordance with embodiments, the secondary bake process is performed below a temperature in a range between approximately 120 to 170° C., at the maximum allowable temperature that the photoresist can endure.

In accordance with embodiments, the hard-bake process performed after the exposure and development processes is performed under nitrogen and/or hydrogen gas atmosphere to neutralize surface charges. The charging is thereby removed, the control of the rotation number or the rinse process time is not required during the DI water rinse process for cleaning. Therefore, the risk of residue remaining after the process for forming the mask pattern is solved, thereby improving the reliability of semiconductor devices.

### DRAWINGS

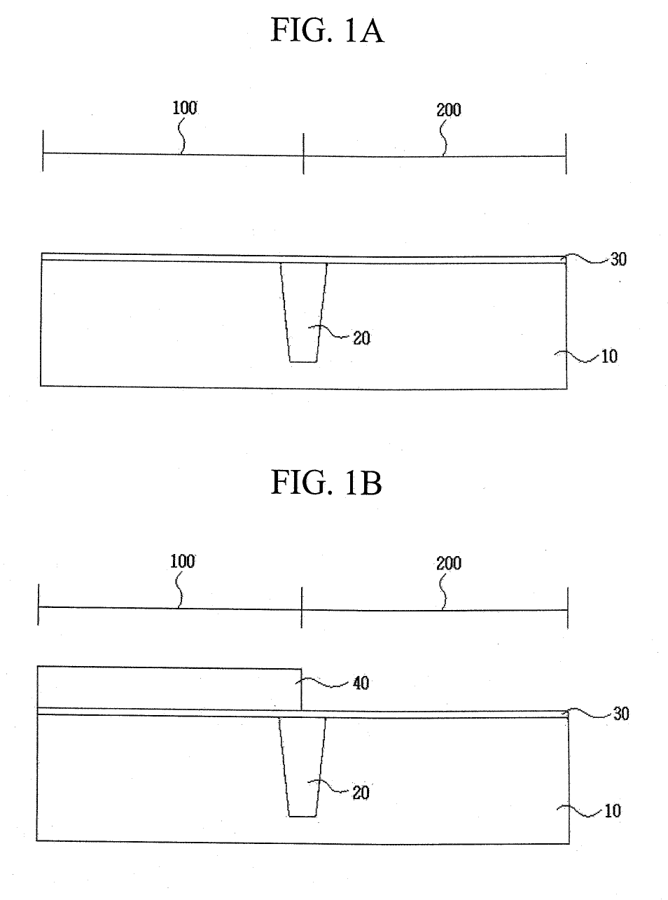

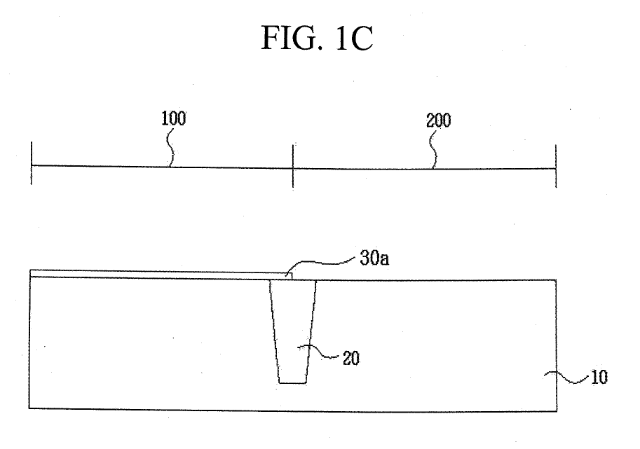

Example FIGS. 1A to 1C illustrate a method for forming a mask pattern in accordance with embodiments.

### DESCRIPTION

In accordance with embodiments, a first photoresist is coated on and/or over an object so as to form a final mask pattern. Here, the object may be a material film to be etched, a wafer to be ion-implanted, or the like. A primary soft-bake process is then performed on the coated photoresist. The soft-bake process is a process that may include curing the coated photoresist. The soft-baked photoresist is then exposed and developed such that portions exposed to light at the time of exposure are removed. Thereby, only a desired portion of the originally coated photoresist remains. A secondary hard-bake process is performed on the remaining photoresist. In accordance with embodiments, the hard-bake process is performed under a nitrogen and/or hydrogen gas atmosphere. The hard bake process is performed at temperature in a range between approximately 120 to 170° C., at the maximum temperature that the photoresist can endure, i.e., the maximum allowable temperature of photoresist.

As the hard-bake process is performed under nitrogen and/or hydrogen gas atmosphere, although charging is caused during DI water rinse process, surface charge is neutralized by the used gas. Particularly, in accordance with embodiments, after removing the portion exposed to light at the time of exposure, the DI water rinse process for cleaning may be performed. In other words, DI water is flowed on the object at a predetermined pressure, performing a high rotation. Charging may be caused during the DI water rinse process. However, in accordance with embodiments, since the bake process is performed under nitrogen and/or hydrogen gas atmosphere, the surface charge is neutralized by the nitrogen and/or hydrogen gas even if the charging is caused during the DI water fines process. Thereby, when performing a deglazing using the completed mask pattern, embodiments can previously prevent the reaction between chemical substances used in the deglazing and a charged region.

Example FIGS. 1A to 1C are cross-sectional views of a method for forming a mask pattern in a process for manufacturing a dual gate device. Referring to example FIG. 1A, a device isolation film 20 is formed in a semiconductor substrate 10, thereby defining a low-voltage device region Lv 100 and a low-voltage device region Hv 200. A gate dielectric film 30 is formed on and/or over the semiconductor substrate 10 defined as the low-voltage device region 100 and high-voltage device region 200. For example, the gate dielectric film may be formed as a gate oxide film on and/or over the semiconductor substrate 10.

Referring to example FIG. 1B, a photoresist 40 for forming a mask pattern is coated on and/or over the gate dielectric film 30. A primary bake process is performed so as to cure the coated photoresist. In the dual gate device, preferably, a thin gate dielectric film 30 is formed on and/or over the low-voltage device region Lv 100, and then a thick gate dielectric film 40 is formed on and/or over the high-voltage device region Hv 200. Thereby, the thin gate dielectric film 30 is formed on and/or over the low-voltage device region by covering the high-voltage device region 200, and then the thick gate dielectric film is formed on and/or over the high-voltage device region by covering the low-voltage device region 100. The photoresist 40 on which the primary bake process is performed is exposed and then developed, removing a portion of the photoresist 40 in the high-voltage device region 200 which is exposed to light at the time of exposure. Thereby, only the photoresist 40 formed on and/or over the low-voltage device region 100 remains. A secondary bake process is performed in order to cure the photoresist 40 in the low-voltage device region 100. The secondary bake process is performed under a nitrogen and/or hydrogen gas atmosphere. The secondary bake process is performed at a temperature in a range between approximately 120 to 170° C., as the maximum allowable temperature of the photoresist 40. A final mask pattern is completed through the secondary bake process.

Referring to example FIG. 1C, the completed mask pattern is used as a mask in the process for removing the gate dielectric film 30 formed in the high-voltage device region 200. In essence, the gate dielectric film 30 is removed from the high-voltage device region 200 using the photoresist 40 formed in the low-voltage device region 100 as a mask. Thereby, the gate dielectric film 30a formed in the low-voltage device region 100 remains. After removing the photoresist 40 remaining in the low-voltage device region 100, a process of forming a thicker gate dielectric film on the high-voltage device region 200 is performed. In accordance with embodiments, the process for forming the mask pattern may also be applied to a process for forming a thick gate dielectric film on and/or over the high-voltage device region 200. In accordance with embodiments, the mask pattern may be a HVGX mask pattern. Therefore, the mask pattern goes through a deglazing process that after forming a HVGX mask pattern, a portion of the gate dielectric film is removed from the high-voltage device region or the low-voltage device region using the HVGX mask pattern.

After removing the portion of the photoresist 40 exposed to light at the time of exposure, the DI water rinse process for cleaning may be performed. In other words, the gate dielectric film 30a may be exposed to DI water at a predetermined pressure, performing a high rotation. Charging may be caused during the DI water rinse process. However, in accordance with * embodiments, since the bake process is performed under nitrogen and/or hydrogen gas atmosphere, the surface charge is neutralized by the use of nitrogen and/or hydrogen gas even if the charging is caused during the DI water fines process. Thereby, when performing a deglazing using the completed mask pattern, embodiments can prevent a reaction between chemical substances used in the deglazing and a charged region.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a photoresist over an object; and then
performing a primary bake process on the photoresist; and then
exposing and developing the photoresist; and then
performing a secondary bake process on the photoresist; and then
forming a mask pattern over the object.

2. The method of claim 1, wherein the object is a film to be etched using the mask pattern as a mask.

3. The method of claim 1, wherein the object is a wafer to be ion-implanted using the mask pattern as a mask.

4. The method of claim 1, wherein exposing and developing the photoresist comprises removing a portion of the photoresist.

5. The method of claim 4, wherein after removing the portion of the photoresist, a cleaning process using a DI water rinse process is performed.

6. The method of claim 1, wherein the secondary bake process is performed under one of a nitrogen gas and a hydrogen gas atmosphere.

7. The method of claim 1, further comprising, after forming the mask pattern, removing a portion of the object using the mask pattern as a mask.

8. The method of claim 1, wherein the primary and secondary bake processes are performed at a temperature in a range between approximately 120 to 170° C.

9. A method comprising:
forming a dielectric film over a semiconductor substrate having a low-voltage device region and a high-voltage device region; and then
coating a photoresist over the dielectric film; and then
curing the photoresist by performing a primary bake process; and then
exposing and developing the cured photoresist to remove a portion of the cured photoresist; and then
curing the photoresist by performing a secondary bake process after exposing and developing the cured photoresist.

10. The method of claim 9, wherein the secondary bake process is performed at a maximum allowable temperature that the photoresist can endure.

11. The method of claim 10, wherein the maximum allowable at a temperature in a range between approximately 120 to 170° C.

12. The method of claim 9, wherein exposing and developing the cured photoresist comprises removing a portion of the photoresist in the high-voltage device region.

13. The method of claim 9, further comprising, after performing the secondary bake process, removing a portion of the dielectric film formed in the high-voltage device region using the mask pattern as a mask.

14. The method of claim 9, further comprising, after exposing and developing the cured photoresist, performing a cleaning process using a DI water rinse process.

15. The method of claim 9, wherein the secondary bake process is performed under one of a nitrogen gas and a hydrogen gas atmosphere.

16. The method of claim 9, wherein the dielectric film comprises an oxide film.

17. A method comprising:
forming a deglazing material over a semiconductor substrate; and then
coating photoresist over the deglazing material; and then
performing a soft-bake process on the photoresist; and then
exposing and developing the photoresist after performing the soft-bake process to remove a portion of the photoresist exposed to light at the time of exposure; and then
performing a hard-bake process on the photoresist exposing and developing the photoresist.

18. The method of claim 17, further comprising, after exposing and developing the photoresist, performing a cleaning process using a DI water rinse process.

19. The method of claim 17, wherein the hard-bake process is performed under one of a nitrogen gas and hydrogen gas atmosphere.

20. The method of claim 17, wherein the primary and secondary bake processes are performed at a temperature in a range between approximately 120 to 170° C.
